(19) United States
(12) Patent Application Publication
(10) Pub. No.: US 2026/0342302 A1
(43) Pub. Date: Oct. 29, 2026

(54) ARRANGEMENT OF RC ELEMENTS FOR MEDIUM VOLTAGE, FOR SWITCHING LOW INDUCTIVE CURRENTS BY MEANS OF HIGH-VOLTAGE VACUUM SWITCHING TECHNOLOGY

(71) Applicant: Siemens Energy Global GmbH & Co. KG, Munich, Bayern (DE)

(72) Inventors: Stefan Giere, Falkensee, Brandenburg (DE); Thomas Heinz, Berlin (DE); Jan Weisker, Brieselang (DE); Rene Schaefer, Bergfelde (DE)

(73) Assignee: Siemens Energy Global GmbH & Co. KG, Munich, Bayern (DE)

(21) Appl. No.: 19/113,038

(22) PCT Filed: Sep. 5, 2023
(86) PCT No.: PCT/EP2023/074305

§ 371 Date: Mar. 19, 2025

(30) Foreign Application Priority Data
Sep. 27, 2022 (DE) 10 2022 210 201.0

(51) Int. Cl. H03H 7/06; H03H 1/00

(52) U.S. Cl. CPC H03H 7/06; H03H 2001/0021

(57) ABSTRACT

A circuit arrangement of RC elements for medium voltage, for implementing an RC filter circuit solution for switching low inductive currents by high-voltage vacuum switching technology in the high-voltage range of >=72.5 kV. Specific arrangements are provided for the limited installation space available in a sub-station.

### CROSS REFERENCE TO RELATED APPLICATIONS

This application is the US National Stage of International Application No. PCT/EP2023/074305 filed 5 Sep. 2023, and claims the benefit thereof, which is incorporated by reference herein in its entirety. The International Application claims the benefit of German Application No. DE 10 2022 210 201.0 filed 27 Sep. 2022.

### FIELD OF INVENTION

The invention relates to an arrangement of RC elements that are designed for medium voltage for realizing an RC filter circuit solution for switching low inductive currents by means of high-voltage vacuum switching technology.

### BACKGROUND OF INVENTION

When switching low inductive currents, as occur in the case of choke applications in high-voltage systems (>=72.5 kV), particular protective measures are necessary. The switching task bears the danger that transient overvoltages can destroy the components of the substation. Here, the choke itself is specifically exposed to a particular danger. The switching media are for example gas circuit breakers and vacuum switching devices.

SF6 circuit breakers are used predominantly in high-voltage systems. In these use cases, the gas circuit breakers are not operated without additional protective measures. These measures serve to reduce the overvoltages that occur during the switching operation.

Applications for choke switching in high-voltage systems (>=72.5 kV) have hitherto been operated with a combination of an electronic control device (controls the exact time of the switch-on or switch-off) and an SF6 circuit breaker with single pole operating mechanism. The solution is cost-intensive, requires an increased outlay during commissioning and bears the risk that the data of the circuit breaker stored in the control device, such as for example the proper times of the switch, change in the course of operation-over the decades. Therefore, the optimum switching time could be changed and the function of arranging single-pole-operated circuit breaker and electronic control device could be adversely affected.

### SUMMARY OF INVENTION

The invention is based on the problem of specifying a solution for how an RC filter circuit can be used in high-voltage electrical energy transmission, in which the high voltage (HV) is greater than or equal to 72.5 kilovolts. Furthermore, the invention is directed to specify variants for the arrangement of the RC elements for efficient insertion into the limited installation space in a substation architecture.

The problem is solved by a circuit arrangement of a plurality of RC elements comprising the features of claim 1.

The use of an RC filter circuit (series circuit made up of resistor R and capacitor C) can reduce the effect of transient overvoltages considerably. One such solution has been used for many years for medium voltage and is prior art there. Consequently, RC filter circuit components are also available for the medium-voltage level.

Transferring this technology to high-voltage applications also reveals choke switching applications for high-voltage vacuum switching devices. The arrangement according to the invention of available, discrete medium-voltage outdoor RC elements constitutes an efficient method for also being able to attend to high-voltage applications. The efficient arrangement of these RC elements may be particularly suitable for being integrated into the corresponding substation architecture. Available installation space is scarce here.

The existing medium-voltage RC solutions essentially cover the voltage ranges up to 36 kV. To enable an expansion to high voltage, a plurality of these elements are interconnected with one another according to the invention. The R and C elements should be accommodated together in a metallic housing G. This housing has a bushing D that is resistant to the outdoors. The electrical series connection of such discrete components makes use at higher voltage levels possible.

In an advantageous development of the invention, an RC element is fastened by a post insulator or a plurality of post insulators SI. This is used on the one hand for mechanical strength and on the other hand for maintaining the distance for voltage isolation.

Advantageous developments of the invention are specified in the dependent claims.

### BRIEF DESCRIPTION OF THE DRAWINGS

The invention is explained in more detail below as an exemplary embodiment, to an extent required for understanding, with reference to figures.

In the figures:

FIG. 1 shows an arrangement according to the invention of three individual RC elements with bushings oriented to the same side,

FIG. 2 shows an arrangement according to the invention of three individual RC elements with bushings oriented to opposite sides,

FIG. 3 shows an arrangement according to the invention of three individual RC elements with bushings aligned in a row, and

FIG. 4 shows an arrangement according to the invention of three individual RC elements in exactly two planes.

### DETAILED DESCRIPTION OF INVENTION

In the figures, identical designations denote identical elements.

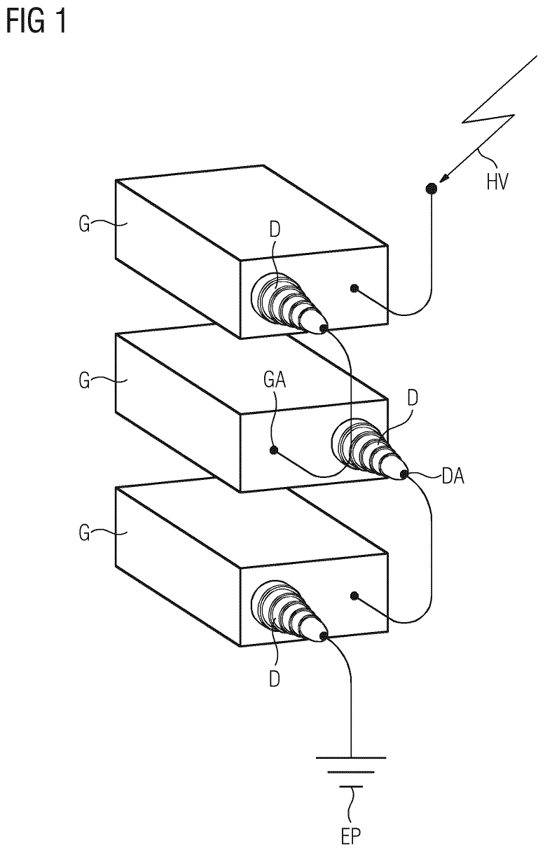

FIG. 1 shows an arrangement according to the invention of the individual RC elements. Three RC elements RC, which in each case have a series circuit made up of a resistor and a capacitor, are arranged with their main surfaces parallel to one another. The RC elements are in each case designed for a medium voltage of up to 36 kV. The RC elements in each case have two electrical connections, a housing connection GA and a bushing connection DA. A bushing connection DA is arranged at the end of the bushing D that faces away from the housing G. The bushing D itself should be arranged on the housing G outside the center of its fastening surface.

In the arrangement according to FIG. 1, the bushing connections DA of a plurality of RC elements face one side. The bushing connections DA of adjacent RC elements can be arranged offset with respect to one another, particularly aligned to the right or left, for better interconnection of the RC elements. The RC elements can be arranged to be stacked above one another or else placed horizontally next to one another. This allows an adaptation to the respective spatial conditions in a substation. The RC elements should be fastened by post insulators which are not illustrated in the figure. These are used on the one hand for mechanical strength and on the other hand for maintaining the distance for voltage isolation.

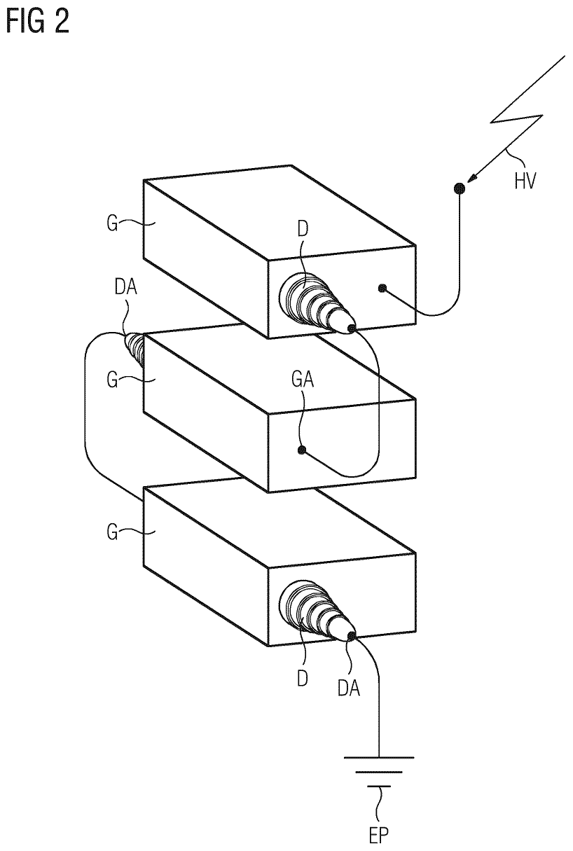

FIG. 2 illustrates a second possible arrangement of the individual RC elements, in which the bushings D of the discrete RC elements are arranged at the front and rear in an alternating manner. For better interconnection of the different RC elements, the bushings are arranged on the left and right in an alternating manner. The RC elements can be arranged to be stacked above one another or else placed horizontally next to one another. This allows an adaptation to the respective spatial conditions in a substation. The RC elements should be fastened by post insulators which are not illustrated in the figure. These are used on the one hand for mechanical strength and on the other hand for maintaining the distance for voltage isolation.

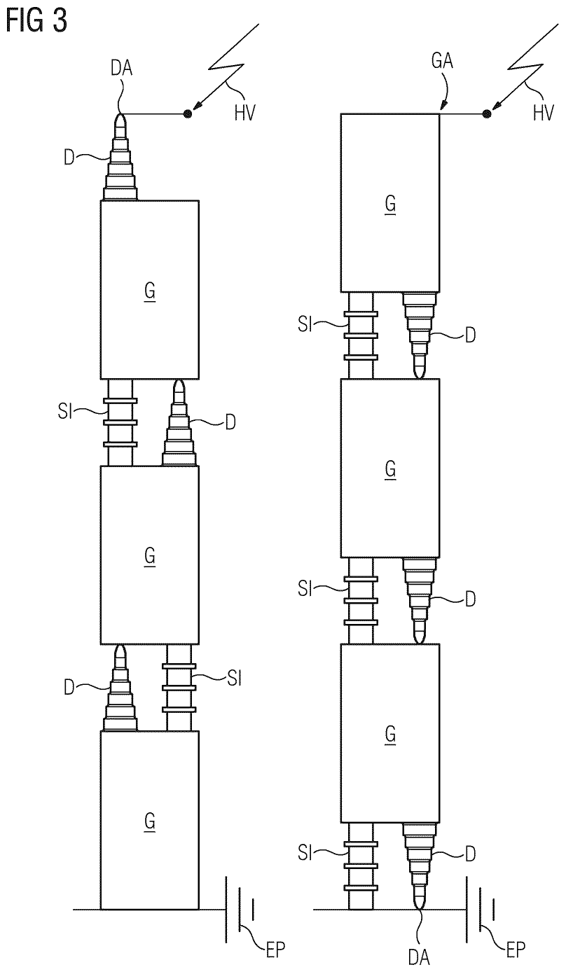

An arrangement is illustrated in FIG. 3, in which the RC elements are stacked on top of one another vertically, but also arranged with their bushings D in a row. Here, there are two options:

As illustrated on the left in the figure, the bushings D are arranged on the left and right in an alternating manner. A post insulator SI is correspondingly arranged on the respectively other side of the RC element, which absorbs the forces of the stacked elements. The housing G of the lowermost RC element is connected directly to a stand area carrying ground potential. This arrangement only requires two post insulators SI for three RC elements.

There is however also the variant, illustrated in FIG. 3 on the right, that all bushings D are arranged on one side and all post insulators SI are arranged on the other side. The lowermost RC element is directly connected to a stand area carrying ground potential using the bushing connection DA of its bushing D. This arrangement requires three post insulators SI for three RC elements.

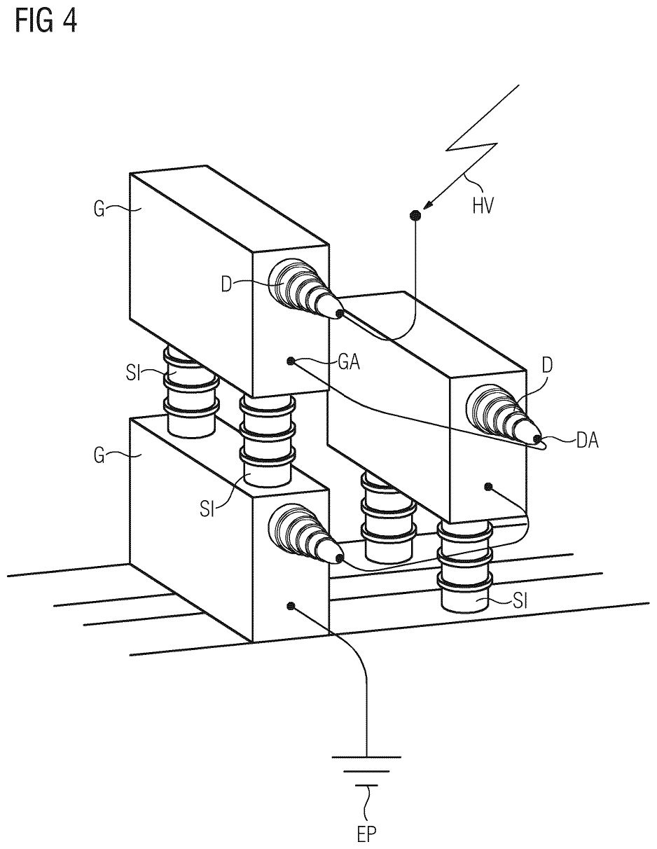

FIG. 4 shows a particularly compact arrangement of the RC elements. Here, the elements are located in exactly two planes next to one another. They are arranged edgewise and the interconnection takes place from an element on the left to an element on the right. Here also, the bushings could always be arranged on one side (as illustrated in the figure) or else in an alternating manner (front/rear). The housing G of the lowermost RC element is connected directly to a stand area carrying ground potential.

The series circuit of the RC elements can be developed such that a high-resistance resistor with the same resistance value is connected in parallel for each RC element. This ensures that the high voltage HV is distributed evenly to the individual RC elements.

An RC element may be a commercially available RC element of the type MV APP from the company TDK Electronics AG.

High voltage in the sense of the invention is understood to mean a voltage of 72.5 kV (kilovolts) and greater, comprising DC voltage, AC voltage and, if three-pole, also three-phase current.

The present invention has been elucidated in detail for explanatory purposes with reference to specific exemplary embodiments. Here, elements of the individual exemplary embodiments may also be combined with one another. The invention is therefore not intended to be limited to individual exemplary embodiments, but merely to be limited by the appended claims.

### LIST OF REFERENCE SIGNS

D—Bushing/out line/voltage bushing
DA—Bushing connection
EP—Ground potential, ground
G—Housing
HV—High voltage
SI—Post insulator

1. A circuit arrangement for the use of electrical RC elements that are designed for medium voltage in high-voltage electrical energy transmission, in which the high voltage (HV) is greater than or equal to 72.5 kilovolts, comprising:
a series circuit comprising a plurality of RC elements which is arranged between a conductor carrying the high voltage (HV) and ground potential (EP), and
wherein the sum of the dielectric strengths of the plurality of RC elements is greater than the high voltage (HV).

2. The circuit arrangement as claimed in claim 1, comprising:
a square, particularly metallic, housing (G), for a respective RC element,
a voltage bushing (D) that is resistant to the outdoors, which is arranged on one side of the housing,
a first connection (GA) on the housing and a second bushing connection (DA) through the voltage bushing (D),
a series circuit made up of at least one electrical resistor and wherein at least one capacitor is arranged in the housing, which is connected to the first connection (GA) or to the second bushing connection (DA).

3. The circuit arrangement as claimed in claim 2, wherein the voltage bushing (D) is arranged off-center on an end face of the housing.

4. The circuit arrangement as claimed in claim 2,
wherein the RC elements are arranged with their main surfaces facing one another and their voltage bushings (D) are arranged offset to one another on one housing side in an alternating manner.

5. The circuit arrangement as claimed in claim 2,
wherein the RC elements are arranged with their main surfaces facing one another and their voltage bushings (D) are arranged on opposite housing sides in an alternating manner.

6. The circuit arrangement as claimed in claim 2,
wherein an RC element is aligned with the voltage bushing (D) of an adjacent RC element.

7. The circuit arrangement as claimed claim 2,
wherein the RC elements are arranged with their main surfaces in exactly two different planes and RC elements of different planes are successively electrically connected.

8. The circuit arrangement as claimed in claim 1,
wherein an RC element is fastened by a post insulator (SI).

9. The circuit arrangement as claimed in claim 1, further comprising:
a high-resistance resistor with the same resistance value which is connected in parallel to each RC element.

10. The circuit arrangement as claimed in claim 1,
wherein the circuit arrangement is interconnected with a choke-switching high-voltage vacuum switching device.
